(19) United States
(12) Patent Application Publication
(10) Pub. No.: US 2005/0249274 A1
(43) Pub. Date: Nov. 10, 2005

(54) Linear filter equalizer

(76) Inventors: Christopher P. Larosa, Crystal Lake, IL (US); Michael J. Carney, Libertyville, IL (US); Chris T. Quanbeck, Arlington Heights, IL (US)

Correspondence Address: MOTOROLA INC, 600 NORTH US HIGHWAY 45, ROOM AS437, LIBERTYVILLE, IL, 60048-5343, US

(21) Appl. No.: 10/842,657

(22) Filed: May 10, 2004

(51) Int. Cl. H03H 7/40

(52) U.S. Cl. 375/232

(57) ABSTRACT

An apparatus (100) and a method (400) suitable for use in a communication device by equalizing an input signal received to mitigate multipath distortion effects present in the input signal in the communication device are provided. A first filter (102) samples the input signal (104) and generates a first filter output (106) based upon the sampled input signal and a filter coefficient array (108). An error signal (112) is then generated based upon a difference between the first filter output (106) and a desired signal (114), and the filter coefficient array (108) is updated based upon a product of the error signal (112) and an adaptation constant (118). A second filter (126) samples a delayed input signal (124) and generates a second filter output (128) based upon the sampled delayed input signal and the filter coefficient array (108).

### FIELD OF THE INVENTION

The present invention generally relates to equalizers, and more specifically to a least-mean-square equalizer effective in communication systems.

### BACKGROUND OF THE INVENTION

In a typical cellular communication system, a transmission signal, or a transmitted waveform, from a cellular base station transmitter to a receiving wireless mobile communication device may be characterized by multiple, independently fading paths. These multiple fading paths, referred to as a multi-path propagation, can cause distortion on received waveforms. There are several receiver architectures designed to mitigate the distortion caused by the multi-path propagation. In Code Division Multiple Access (“CDMA”) systems, a receiver in a wireless mobile communication device typically employs a RAKE architecture, which uses several baseband correlators, or Rake fingers, to individually process each component of multi-path components. Correlator outputs are then combined to achieve improved performance in recovering the transmitted waveform. The RAKE architecture is also able to support soft handover, which occurs when the receiver combines waveforms from multiple cellular base stations.

Alternative receiver devices, such as linear equalizers, employ filtering techniques to optimize performance in a multi-path environment. These equalizers are common in many cellular communications systems including Global System for Mobile communications (“GSM”). However, these equalizers are not common in CDMA cellular networks for two primary reasons. First, linear equalizers do not inherently support soft handover techniques. Distinct equalizers would be needed for each base station within a reception range of the wireless mobile communication device, and would increase the cost of the wireless mobile communication device. Second, equalizer performance is less effective in an environment where characteristics of the transmission channel are rapidly changing.

The next generation, or the third generation (“3G”), of cellular systems is expected to provide high data rates, allowing consumers to experience added benefits, such as real-time video. In a high speed downlink packet access (“HSDPA”) system, high data rate transmissions are expected to exhibit characteristics which make an equalizer preferable to a conventional RAKE receiver, including: 1) the signal is transmitted by a single base station, thus eliminating the need to support soft handover; 2) a high-order modulation scheme with high symbol rates may be employed; and 3) the ratio of the desired signal to interference is typically high relative to the ratio for common voice channels. Although these conditions favor equalization, the rapidly-changing channel environment continues to be a source of degradation for a conventional equalizer.

Equalizers employing iterative coefficient updating include the Least-Mean-Square (“LMS”), Block LMS, and Recursive-Least-Square (“RLS”) algorithms. By utilizing a recursive approach, these equalizers adapt to their environment and achieve satisfactory performance in transmission channels that are varying relatively slowly. An LMS equalizer, for example, iteratively modifies its filter coefficients in an attempt to match a desired or “target” signal. In a typical LMS equalizer used in a cellular telecommunication application, an input signal, u(n), consisting of a received baseband waveform and n indicating the iteration number, is passed through a tapped delay line having N taps. At each tap, the input signal is sampled and the sampled signal is multiplied by its corresponding filter coefficient, wᵢ(n) where i is the location index of the tap. The sum of these sample-coefficient products is used to generate a filter output, y(n), which is then compared to a desired signal d(n). The difference between the filter output, y(n), and the desired signal, d(n), forms an error signal, e(n), which is used to update the filter coefficients.

The algorithm used to generate the next set of coefficients, w(n+1), can be expressed as:

$$\underline{w} ( n + 1 ) = \underline{w} ( n ) + μ \underline{u} ( n ) e * ( n ) where \\ \begin{matrix}\underline{u} ( n ) = column vector of current input samples \\ = {[ u ( n ) , u ( n - 1 ) , … , u ( n - N ) ]}^{T} ,\end{matrix} \\ \begin{matrix}\underline{w} ( n ) = column vector of current filter coefficients \\ = {[ {w}_{0} ( n ) , {w1}_{1} ( n ) , … , {w}_{N - 1} ( n ) ]}^{T} , and\end{matrix} \\ \begin{matrix}e ( n ) = error signal \\ = d ( n ) - y ( n ) , where\end{matrix} \\ \begin{matrix}μ = the adaptation constant , and \\ n = iteration number\end{matrix} \qquad ( 1 )$$

When an LMS equalizer operates properly in a multipath environment, the distortion imposed by the transmission channel is removed from the filter output y(n). As a result, this output approximates the desired signal, and improved receiver performance is obtained. In a CDMA handset implementing this conventional approach, the filter output would then be sent to a receiver back-end, which performs despreading, correlation, and decoding of the filter output required to recover the transmitted data sequence. The coefficient adaptation expressed in Equation (1) is based upon an algorithm that attempts to minimize the mean-square error between the filter output and the target signal. Ideally, this error would approach the result produced by the Wiener solution, which is optimal. Because the statistics of the input signal vary in time, the mean-square error from the LMS filter will not, in general, converge to this ideal solution. A misadjustment, which is a measure of deviation of the mean-square error from the optimal solution, can be decoupled into two components: a gradient, or noise error, component and a lag error component. An adaptation coefficient, or step size, μ, affects these two components in opposite ways. Specifically, increasing the adaptation coefficient μ will reduce the lag error while making the filter more susceptible to noise. Conversely, decreasing the adaptation coefficient μ will improve performance in noise environments while increasing the error of the lag component.

In a high mobility environment, an LMS filter, using small adaptation coefficients to reduce the noise error component, tends to track the time-varying transmission channel. However, the small adaptation coefficients have an undesirable effect of increasing the lag error, which becomes more pronounced as the mobility, such as vehicle speed, is increased.

### BRIEF DESCRIPTION OF THE DRAWINGS

FIG. 1 is an exemplary block diagram of an embodiment of a linear filter equalizer in accordance with the present invention;

FIG. 2 is an exemplary block diagram of an embodiment of the first filter configured to process the received signal in the linear equalizer in accordance with the present invention;

FIG. 3 is an exemplary block diagram of an embodiment of the second filter configured to process the delayed received signal in the linear equalizer in accordance with the present invention; and

FIG. 4 is an exemplary flowchart illustrating a method in a communication device for equalizing a received signal in accordance with the present invention.

### DETAILED DESCRIPTION OF THE PREFERRED EMBODIMENTS

The present invention provides an apparatus and a method suitable for use in a communication device by equalizing a received signal to mitigate multipath distortion effects present in the received signal in the communication device. The communication device may typically be a wireless communication device such as a cellular telephone. A transmitted signal directed to the wireless communication device may be received by the wireless communication device after traveling through multiple independent paths, or fading paths. As a result, a received signal is a composite of several faded transmitted signals having multipath distortion effects. To mitigate the effect of the multipath distortion, the present invention utilizes two linear filters such as tapped delay lines. A first filter accepts a received signal and attempts to track the received signal by utilizing various techniques such as, but not limited to, minimizing a mean-square-error in a manner similar to that of a conventional least-mean-square (“LMS”) filter. Instead of forwarding an output from the first filter directly to a back end of a receiver to recover a transmitted waveform as in a conventional wireless communication device, the output from the first filter is only used to generate filter coefficients. A difference between the output from the first filter and a desired signal is used to generate an error signal. The error signal is then scaled by an adaptation constant to generate the filter coefficients. A second filter accepts a delayed received signal, which is generated by adding a delay to the received signal. This added delay effectively compensates for a lag error of a conventional LMS solution, and allows input data samples in the second filter to be better aligned with the filter coefficients. Two parameters, the adaptation constant and the delay, are adjusted to compensate for noise and lag error components, respectively, of the received signal. The values of the parameter pair can be chosen based on a rate of change of the received signal, which may be based on various techniques such as, but not limited to, Doppler and velocity estimation.

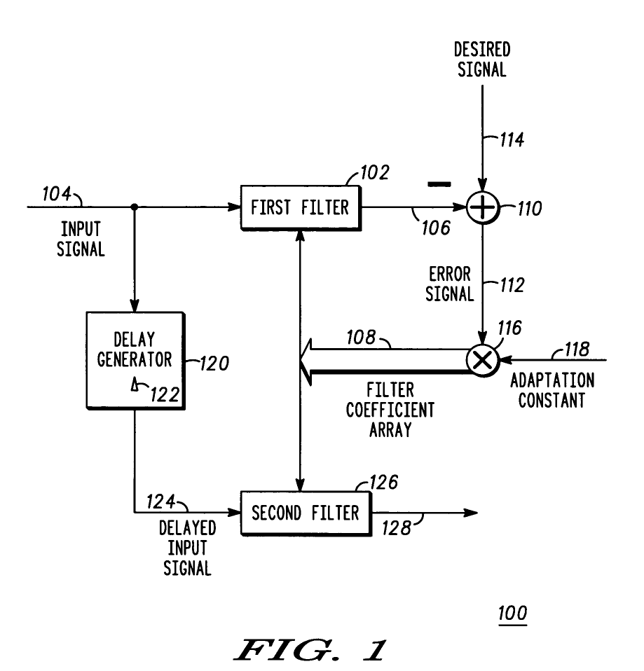

FIG. 1 is an exemplary block diagram of an embodiment of a linear filter equalizer 100 in accordance with the present invention. The linear filter equalizer 100 comprises a first filter 102, which is a linear filter such as a tapped delay line having N taps. The first filter 102 receives an input signal 104 such as the received signal having distortion due to the multipath fading. The first filter 102 is configured to function as a conventional tapped delay line, and samples the input signal 104 at each tap, generating a plurality of sampled input signals, or first tap signals (not shown). A first filter output 106 is then generated based upon the plurality of first tap signals and a filter coefficient array 108. The filter coefficient array 108 can be initially assigned a default value and can later be updated. An error signal generator 110 is coupled to the first filter 102, and is configured to generate an error signal 112 based upon the first filter output 106 and a desired signal 114, such as a difference between the first filter output 106 and the desired signal 114. The error signal 112 is used to update the filter coefficient array 108. A filter coefficient generator 116 is coupled to the error signal generator 110, and is configured to generate and update the filter coefficient array 108 based upon the error signal 112 and an adaptation constant 118, which may be used to scale the error signal 112. An updated filter coefficient array may be further based upon the input signal 104, a previously generated filter coefficient array, and the scaled error signal. The linear filter equalizer 100 further comprises a delay generator 120, which is configured to accept the input signal 104 and to add a delay time 122 to the input signal 104, generating a delayed input signal 124. A second filter 126, which is another linear filter such as a tapped delay line having M taps, is coupled to the filter coefficient generator 116 and to the delay generator 120. The number of taps of the first filter 102 and that of the second filter 126 may be the same. The second filter 126 samples the delayed input signal 124 at each tap, generating a plurality of sampled delayed input signals, or second tap signals (not shown). By adding the delay time 122 to the input signal 104, the delayed input signal 124 is better compensated for a lag error, and the plurality of second tap signals in the second filter 126 is better aligned with the filter coefficient array 108. The second filter 126 is further configured to generate a second filter output 128 based upon the plurality of second tap signals and the filter coefficient array 108. The filter coefficient array 108 may assume various sizes having various number of array elements based upon the number of taps of the first filter 102 and the second filter 126. Both the adaptation constant 118 and the delay time 122 may be varied based upon a rate of change of the input signal 104.

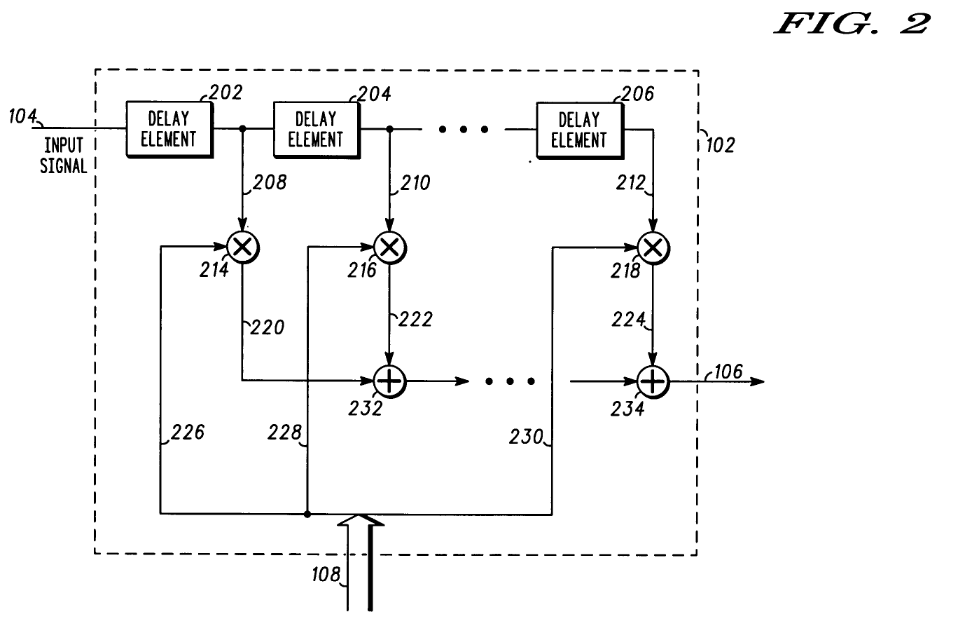

FIG. 2 is an exemplary block diagram of an embodiment of the first filter 102 configured to process the received signal 104 in the linear equalizer 100 in accordance with the present invention. The first filter 102, shown as a tapped delay line, has a plurality of delay elements (only three delay elements 202, 204, and 206 are shown). Each of the plurality of delay elements 202, 204, and 206 is configured to sample the input signal 104 at a predetermined rate such as a half or full chip rate and generates a corresponding first tap signal (only three first tap signals 208, 210, and 212 are shown). The first filter 102 further includes a plurality of first filter tap multipliers (only three first filter tap multipliers 214, 216, and 218 are shown) corresponding to the plurality of delay elements 202, 204, and 206. Each of the plurality of first filter tap multipliers 214, 216, and 218 is coupled to a corresponding delay element 202, 204, or 206, and to the filter coefficient generator 116. Each of the plurality of first filter tap multipliers 214, 216, and 218 is configured to multiply the corresponding first tap signal 208, 210, and 212 with a corresponding first tap coefficient 226, 228, and 230 of the filter coefficient array 108 to produce an element product 220, 222, and 224. For example, the first filter tap multiplier 214 is configured to multiply the first tap signal 208 from the delay element 202 with the corresponding first tap coefficient 226 to produce the element product 220. All of the element products 220, 222, and 224 are summed by a plurality of adders (only two adders 232 and 234 are shown) to generate the first filter output 106, which is then used to update the filter coefficient array 108.

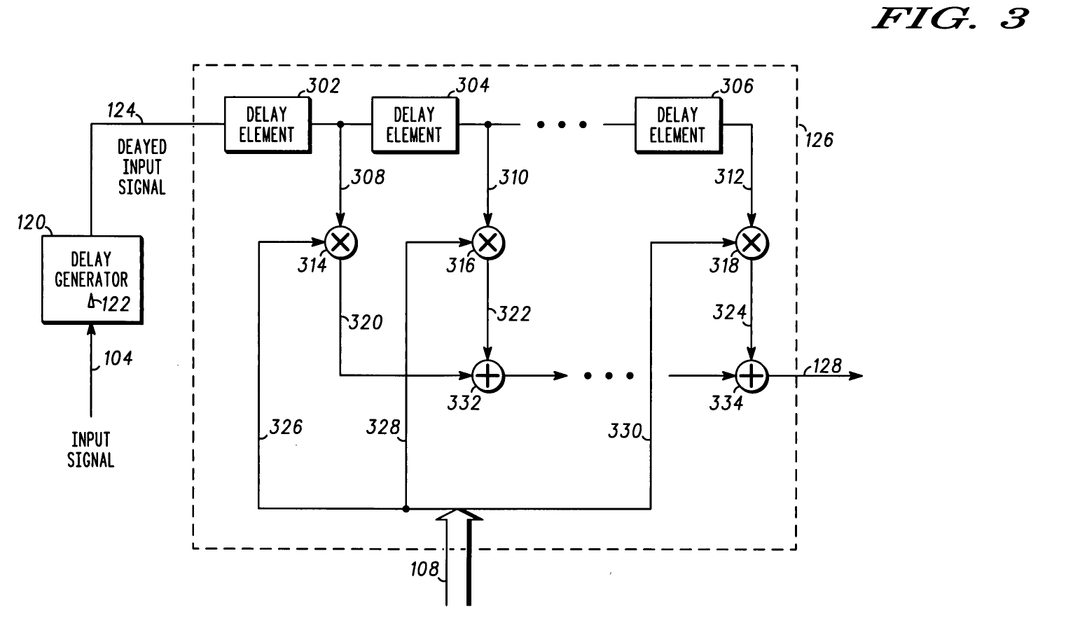

FIG. 3 is an exemplary block diagram of an embodiment of the second filter 126 configured to process the delayed input signal 124 in the linear equalizer 100 in accordance with the present invention. The second filter 126 is similar to the first filter 102 except that the second filter 126 receives the delayed input signal 124 and its output, the second filter output 128, is not used to generate or update the filter coefficient array 108 but is forwarded to a receiver back-end. As previously described, the delayed input signal 124 is generated by adding the delay time 122 to the input signal 104 by the delay generator 120. The second filter 126, shown as a tapped delay line, has a plurality of delay elements (only three delay elements 302, 304, and 306 are shown). Each of the plurality of delay elements 302, 304, and 306 is configured to sample the delayed input signal 124 at a predetermined rate such as a half or full chip rate and generates a corresponding second tap signal (only three second tap signals 308, 310, and 312 are shown). The second filter 126 further includes a plurality of second filter tap multipliers (only three second filter tap multipliers 314, 316, and 318 are shown) corresponding to the plurality of delay elements 302, 304, and 306. Each of the plurality of second filter tap multipliers 314, 316, and 318 is coupled to a corresponding delay element 302, 304, or 306, and to the filter coefficient generator 116. Each of the plurality of second filter tap multipliers 314, 316, and 318 is configured to multiply the corresponding second tap signal 308, 310, and 312 with a corresponding second tap coefficient 326, 328, and 330 of the filter coefficient array 108 to produce an element product 320, 322, or 324. For example, the second filter tap multiplier 314 is configured to multiply the second tap signal 308 from the delay element 302 with the corresponding second tap coefficient 326 to produce the element product 320. All of the element products 320, 322, and 324 are summed by a plurality of adders (only two adders 332 and 334 are shown) to generate the second filter output 128.

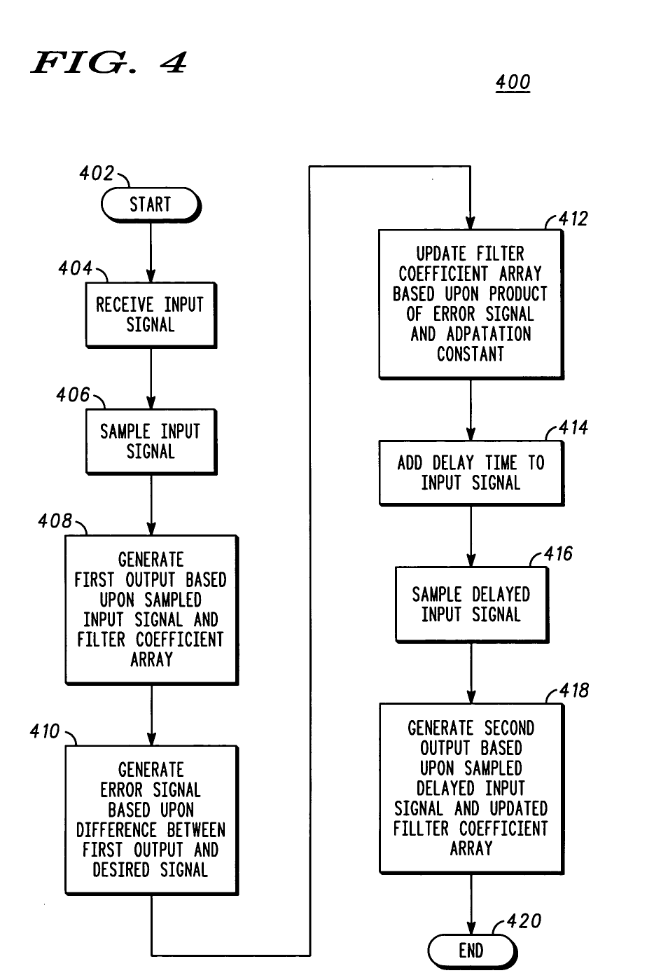

FIG. 4 is an exemplary flowchart 400 illustrating a method in a communication device for equalizing an input signal in accordance with the present invention. The process begins in block 402 and the input signal is received in block 404. The input signal is then sampled in block 406. In block 408, a first output is generated based upon the sampled input signal and a filter coefficient array. The first output may be generated by using a tapped delay line. An error signal is generated in block 410 based upon a difference between the first output and a desired signal. The error signal is then used in block 412 to update the filter coefficient array, which is based upon a product of the error signal and an adaptation constant. In block 414, a delay time is added to the input signal, and the delayed input signal is sampled in block 416. A second output is then generated in block 418 based upon the sampled delayed input signal and the updated filter coefficient array. The second output may also be generated by using another tapped delay line. The process then terminates in block 420. The process may further include an evaluation of a rate of change of the input signal, and the adaptation constant in block 412 and the delay time in block 414 may be varied based upon the rate of change of the input signal.

While the preferred embodiments of the invention have been illustrated and described, it is to be understood that the invention is not so limited. Numerous modifications, changes, variations, substitutions and equivalents will occur to those skilled in the art without departing from the spirit and scope of the present invention as defined by the appended claims.

1. A linear filter equalizer comprising:
a first filter configured to receive an input signal, the first filter further configured to generate a first filter output based upon a plurality of sampled input signals weighted by a filter coefficient array;
an error signal generator coupled to the first filter, the error signal generator configured to generate an error signal based upon the first filter output and a desired signal;
a filter coefficient generator coupled to the error signal generator, the filter coefficient generator configured to generate the filter coefficient array based upon the error signal and an adaptation constant;
a delay generator configured to add a delay time to the input signal to generate a delayed input signal; and
a second filter coupled to the filter coefficient generator and to the delay generator, the second filter configured to generate a second filter output based upon a plurality of sampled delayed input signals weighted by the filter coefficient array.

2. The linear filter equalizer of claim 1, wherein the error signal based upon the first filter output and the desired signal includes an error signal generated based upon a difference between the first filter output and the desired signal.

3. The linear filter equalizer of claim 1, wherein the filter coefficient array generated is further based upon at least one of the input signal and a previous filter coefficient array.

4. The linear filter equalizer of claim 1, wherein the adaptation constant is varied based upon a rate of change of the input signal.

5. The linear filter equalizer of claim 1, wherein the delay time is varied based upon a rate of change of the input signal.

6. The linear filter equalizer of claim 1, wherein at least one of the first filter and the second filter is a tapped delay line comprising a plurality of delay elements.

7. The linear filter equalizer of claim 6, wherein the filter coefficient array has a plurality of array elements corresponding to the plurality of delay elements.

8. The linear filter equalizer of claim 1, wherein:
the first filter is a tapped delay line comprising a plurality of first filter delay elements.
the second filter is a tapped delay line comprising a plurality of second filter delay elements, the plurality of second filter delay elements equal in numbers as the plurality of first filter delay elements, and
the filter coefficient array has a plurality of array elements corresponding to the plurality of the first filter delay elements and to the plurality of second filter delay elements.

9. The linear filter equalizer of claim 8, wherein the plurality of array elements corresponding to the plurality of the first filter delay elements also corresponds to the plurality of the second filter delay elements.

10. A wireless communication device having a linear filter equalizer comprising:
a first filter configured to accept an input signal, the first filter further configured to generate a first filter output based upon a plurality of sampled input signals weighted by a filter coefficient array;
an error signal generator coupled to the first filter, the error signal generator configured to generate an error signal based upon the first filter output and a desired signal;
a filter coefficient generator coupled to the error signal generator, the filter coefficient generator configured to generate the filter coefficient array based upon the error signal and an adaptation constant;
a delay generator configured to add a delay time to the input signal to generate a delayed input signal; and
a second filter coupled to the filter coefficient generator and to the delay generator, the second filter configured to generate a second filter output based upon a plurality of sampled delayed input signals weighted by the filter coefficient array.

11. The wireless communication device of claim 10, wherein the error signal based upon the first filter output and the desired signal includes an error signal generated based upon a difference between the first filter output and the desired signal.

12. The wireless communication device of claim 10, wherein the filter coefficient array generated is further based upon at least one of the input signal and a previous filter coefficient array.

13. The wireless communication device of claim 10, wherein the adaptation constant is varied based upon a rate of change of the input signal.

14. The wireless communication device of claim 10, wherein the delay time is varied based upon a rate of change of the input signal.

15. The wireless communication device of claim 10, wherein at least one of the first filter and the second filter is a tapped delay line comprising a plurality of delay elements.

16. The wireless communication device of claim 10, wherein the filter coefficient array has a plurality of array elements corresponding to the plurality of delay elements.

17. The wireless communication device of claim 10, wherein:
the first filter is a tapped delay line comprising a plurality of first filter delay elements.
the second filter is a tapped delay line comprising a plurality of second filter delay elements, the plurality of second filter delay elements equal in numbers as the plurality of first filter delay elements, and
the filter coefficient array has a plurality of array elements corresponding to the plurality of the first filter delay elements and to the plurality of second filter delay elements.

18. The wireless communication device of claim 17, wherein the plurality of array elements corresponding to the plurality of the first filter delay elements also corresponds to the plurality of the second filter delay elements.

19. A method in a linear filter equalizer for equalizing an input signal, the method comprising:
receiving the input signal;
sampling the input signal;
generating a first output based upon the sampled input signal and a filter coefficient array;
generating an error signal based upon the first output and a desired signal;
updating the filter coefficient array based upon the error signal and an adaptation constant;
delaying the input signal by a delay time;
sampling the delayed input signal; and
generating a second output based upon the sampled delayed input signal and the updated filter coefficient array.

20. The method of claim 19, wherein generating an error signal based upon the first output and a desired signal includes generating an error signal based upon a difference between the first filter output and the desired signal.

21. The method of claim 19, wherein updating the filter coefficient array based upon the error signal and the adaptation constant includes updating the filter coefficient array based upon a product of the error signal and an adaptation constant.

22. The method of claim 19, further comprising:
evaluating a rate of change of the input signal; and
varying the adaptation constant based upon the rate of change of the input signal.

23. The method of claim 19, further comprising:
evaluating a rate of change of the input signal; and
varying the delay time based upon the rate of change of the input signal.

24. The method of claim 19, wherein generating a first output includes using a tapped delay line.

25. The method of claim 19, wherein generating a second output includes using a tapped delay line.
